(19) United States
(12) Patent Application Publication
(10) Pub. No.: US 2016/0293859 A1
(43) Pub. Date: Oct. 6, 2016

(54) SOLID-STATE IMAGING DEVICE AND ELECTRONIC APPARATUS

(71) Applicant: SONY CORPORATION, Tokyo (JP)

(72) Inventor: Ichiro TAKEMURA, Kanagawa (JP)

(21) Appl. No.: 15/037,430

(22) PCT Filed: Nov. 19, 2014
(86) PCT No.: PCT/JP2014/005834

§ 371 Date: May 18, 2016

(30) Foreign Application Priority Data
Nov. 27, 2013 (JP) 2013-244953

(51) Int. Cl. H01L 51/00; C09B 69/00; C09B 69/10; C09B 47/04; C09B 48/00

(52) U.S. Cl. CPC H01L 51/0078; H01L 51/0047; H01L 51/0067; H01L 51/0035; C09B 47/04; C09B 48/00; C09B 69/102; C09B 69/109; C09B 69/00; H01L 27/307

(57) ABSTRACT

Devices, methods, and electronic apparatuses directed towards solid-state imaging devices that include: a pixel including an organic photoelectric conversion section, the organic photoelectric conversion section including an organic photoelectric conversion film (62), the organic photoelectric conversion film performing photoelectric conversion; a pigment included in the organic photoelectric conversion film, the pigment being two or more polymerized monomers, and the pigment having absorbance in ultraviolet to infared regions.

### CROSS REFERENCE TO RELATED APPLICATIONS

This application claims the benefit of Japanese Priority Patent Application JP 2013-244953 filed Nov. 27, 2013, the entire contents of which are incorporated herein by reference.

### TECHNICAL FIELD

The present disclosure relates to a solid-state imaging device and an electronic apparatus, and particularly to a solid-state imaging device and an electronic apparatus capable of improving heat resistance of an organic photoelectric conversion film of the solid-state imaging device.

### BACKGROUND ART

Subphthalocyanine (SubPc) has been used as pigment, colorant, or the like for a photosensitive optoelectronic device or a color filter for a plasma display in the related art (see PTL 1 to PTL 5, for example).

### CITATION LIST

### Patent Literature

PTL 1: Japanese Unexamined Patent Application Publication (Translation of PCT Application) No. 2009-538529

PTL 2: Japanese Unexamined Patent Application Publication No. 2008-216589

PTL 3: Japanese Patent No. 4544914

PTL 4: Japanese Patent No. 4652213

PTL 5: Japanese Patent No. 4579041

### SUMMARY OF INVENTION

### Technical Problem

However, when monomer pigment such as subphthalocyanine is used as a material of the organic photoelectric conversion film in the solid-state imaging device, the monomer pigment does not have heat resistance. This is problematic because the subphthalocyanine will not function as desired due to the negative effects of the heat.

It is desirable to improve the heat resistance of the organic photoelectric conversion film in the solid-state imaging device.

### Solution to Problem

According to an illustrative embodiment of the present disclosure, there is provided solid-state imaging devices including: a pixel which has an organic photoelectric conversion section which performs photoelectric conversion by an organic photoelectric conversion film, wherein the organic photoelectric conversion film is formed by pigment which is configured of polymer with absorbance in ultraviolet to infrared regions.

According to another illustrative embodiment of the present disclosure, there is provided electronic apparatuses including: a solid-state imaging device including a pixel which has an organic photoelectric conversion section which performs photoelectric conversion by an organic photoelectric conversion film, the organic photoelectric conversion film being formed by pigment which is configured of polymer with absorbance in ultraviolet to infrared regions.

In the embodiments of the present disclosure, the organic photoelectric conversion film in the pixel including the organic photoelectric conversion section which performs photoelectric conversion by the organic photoelectric conversion film is formed by the pigment which is configured of the polymer with the absorbance in the ultraviolet to infrared regions.

According to a further illustrative embodiment of the present disclosure, there is provided solid-state imaging devices, including: a pixel including an organic photoelectric conversion section, the organic photoelectric conversion section including an organic photoelectric conversion film, the organic photoelectric conversion film performing photoelectric conversion; a pigment included in the organic photoelectric conversion film, the pigment being two or more polymerized monomers, and the pigment having absorbance in ultraviolet to infrared regions.

According to yet a further illustrative embodiment of the present disclosure, there is provided electronic apparatuses, comprising: a solid-state imaging device, including: a pixel including an organic photoelectric conversion section, the organic photoelectric conversion section including an organic photoelectric conversion film, the organic photoelectric conversion film performing photoelectric conversion; a pigment included in the organic photoelectric conversion film, the pigment being two or more polymerized monomers, and the pigment having absorbance in ultraviolet to infrared regions.

The solid-state imaging device and the electronic apparatus may be independent apparatuses or may be modules which are embedded in another apparatus.

### Advantageous Effects of Invention

According to the embodiments of the present disclosure, it is possible to improve the heat resistance of the organic photoelectric conversion film in the solid-state imaging device.

In addition, the advantages described herein are not necessarily limited, and any of the advantages described in this disclosure may be achieved.

### BRIEF DESCRIPTION OF DRAWINGS

FIG. 1 is an illustrative diagram showing a method of producing mu-oxo-subphthalocyanine dimer.

FIG. 2 is an illustrative diagram showing an evaluation sample which is produced for the first experiment.

FIG. 3A is an illustrative diagram showing a spectral property of an evaluation sample in which mu-oxo-subphthalocyanine is used.

FIG. 3B is an illustrative diagram showing a spectral property of an evaluation sample in which mu-oxo-subphthalocyanine is used.

FIG. 3C is an illustrative diagram showing a spectral property of an evaluation sample in which mu-oxo-subphthalocyanine is used.

FIG. 4A is an illustrative diagram showing a spectral property of an evaluation sample in which subphthalocyanine chloride is used.

FIG. 4B is an illustrative diagram showing a spectral property of an evaluation sample in which subphthalocyanine chloride is used.

FIG. 4C is an illustrative diagram showing a spectral property of an evaluation sample in which subphthalocyanine chloride is used.

FIG. 5 is an illustrative diagram showing an evaluation sample which is produced for the second experiment.

FIG. 6 is an illustrative diagram showing a rate of change in external quantum efficiency of a device before and after heating.

FIG. 7 is an illustrative diagram showing an experimental result.

FIG. 8 is an illustrative diagram showing an experimental result.

FIG. 9 is an illustrative diagram showing a schematic configuration of a solid-state imaging device according to the present disclosure.

FIG. 10 is an illustrative cross-sectional view of a pixel in the solid-state imaging device.

FIG. 11 is an illustrative block diagram showing a configuration example of an imaging apparatus as an electronic apparatus according to the present disclosure.

### DESCRIPTION OF EMBODIMENTS

<Method of Producing Mu-Oxo-Subphthalocyanine Dimer>

The present disclosure relates to pigment configured of polymer with absorbance in ultraviolet to infrared regions (e.g., within a range of 10²-10⁶ A), which is suitable as a material of an organic photoelectric conversion film in a solid-state imaging device. First, mu-oxo-subphthalocyanine dimer will be described as an example of the pigment according to the present disclosure.

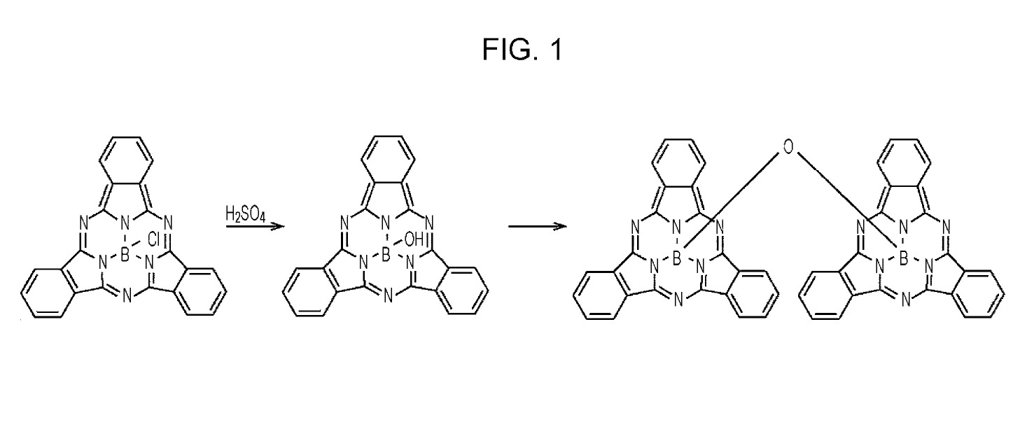

FIG. 1 is an illustrative diagram showing a method of producing mu-oxo-subphthalocyanine dimer.

Subphthalocyanine chloride as subphthalocyanine monomer is induced to subphthalocyanine hydroxide by hydrolysis under an acidic condition of sulfuric acid or the like. The subphthalocyanine hydroxide is heated under a low-pressure condition by using a mantle heater, and a resultant substance is purified by using purification means such as column chromatogoraphy, and mu-oxo-subphthalocyanine dimer is acquired. In the experiment described below, a substance acquired by purifying mu-oxo-subphthalocyanine dimer, obtained as described above by using a sublimation and purification apparatus, was used as subphthalocyanine polymer.

Subphthalocyanine polymer can be expressed by the following Formula (B1).

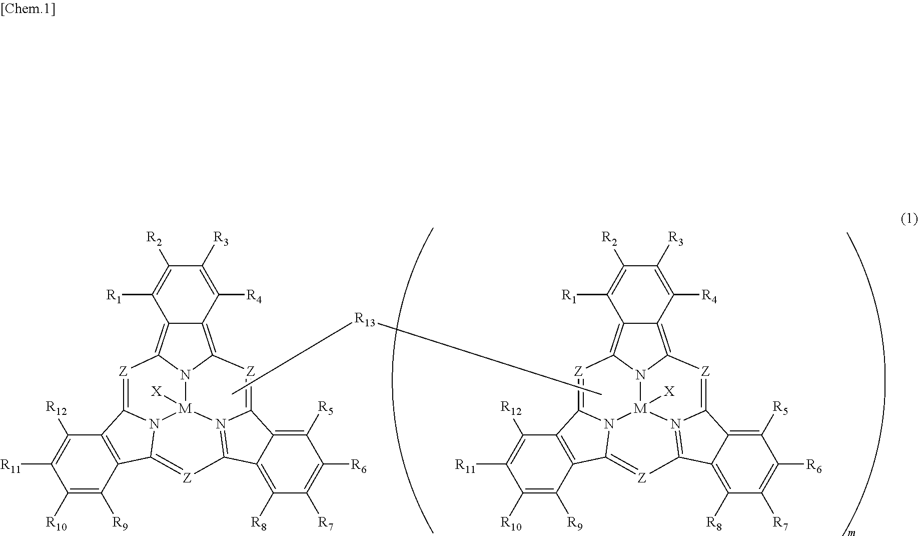

In Formula (B1), R₁ to R₁₂, M, X, and Z are independently selected, R₁ to R₁₂ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₁₃ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₁₂ may be a part of a condensed aliphatic ring or of a condensed aromatic ring, the ring may contain one or more atoms other than carbon atoms, and furthermore, R₁₃ is selected from a group of the functional groups used for R₁ to R₁₂ which are coupled with one or more subphthalocyanines or a subporphyrin ring via M or a portion of any of R₁ to R₁₂, M is boron, bivalent metal, or trivalent metal, X is selected from a group including an anionic group that is introduced when R₁₃ is not directly coupled with M and the group of the functional groups which are used for R₁ to R₁₂ that can be coupled with M, Z is represented by N, CH, or CH₁₄, and R₁₄ is selected from a group of the functional groups used for R₁ to R₁₂.

<Experiment Regarding Variation in Spectral Shape>

First, description will be given of a first experiment for evaluating variations in a spectral shape when subphthalocyanine polymer and subphthalocyanine monomer are heated.

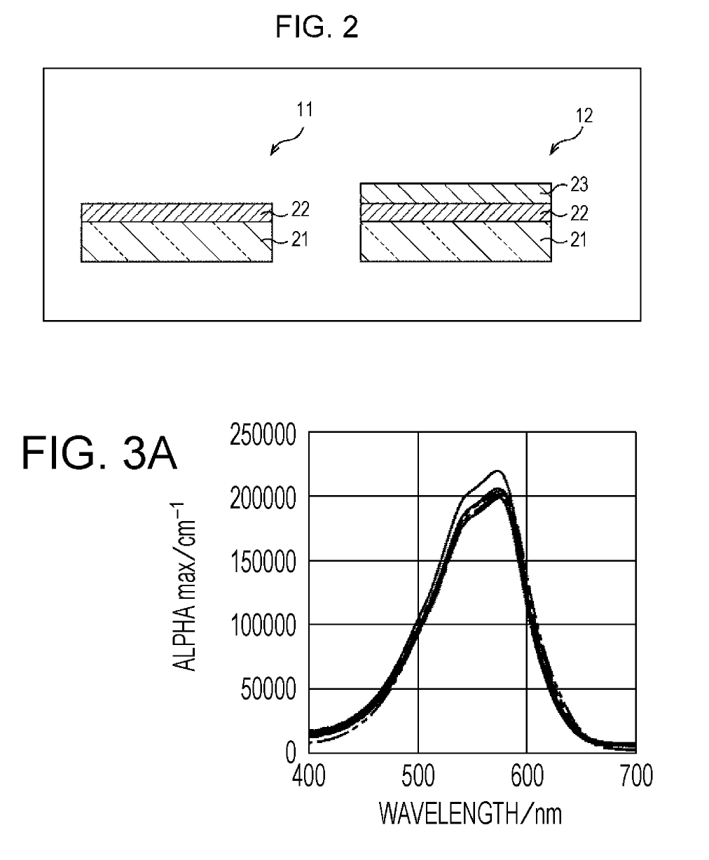

In the first experiment, Sample 11 and Sample 12 shown in FIG. 2 were used as samples for evaluation.

Sample 11 was obtained by forming an organic thin film 22 on a quartz substrate 21 by deposition, and subphthalocyanine chloride was used as monomer and mu-oxo-subphthalocyanine dimer was used as polymer for the organic thin film 22.

Sample 12 was obtained by further forming an ITO (Indium Tin Oxide) film 23 on the organic thin film 22 of Sample 11 in order to acquire an environment close to an actual device that has to have annealing resistance. Film thicknesses of the organic thin film 22 and the ITO film 23 were set to about 50 nm, for example.

In the first experiment, spectral properties of Samples 11 and 12 before and after heating were measured under a plurality of heating conditions, such as a heating temperature of 160 degrees Celsius or 245 degrees Celsius, and a heating time of 5 minutes, 60 minutes, or 210 minutes.

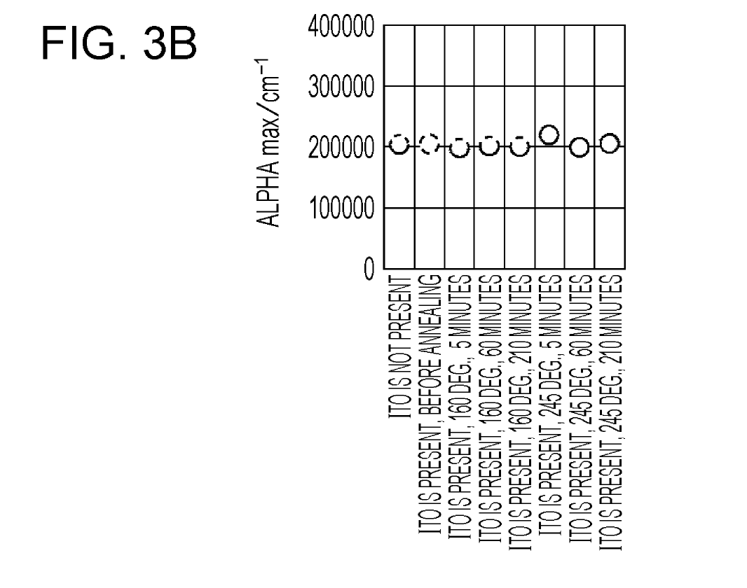

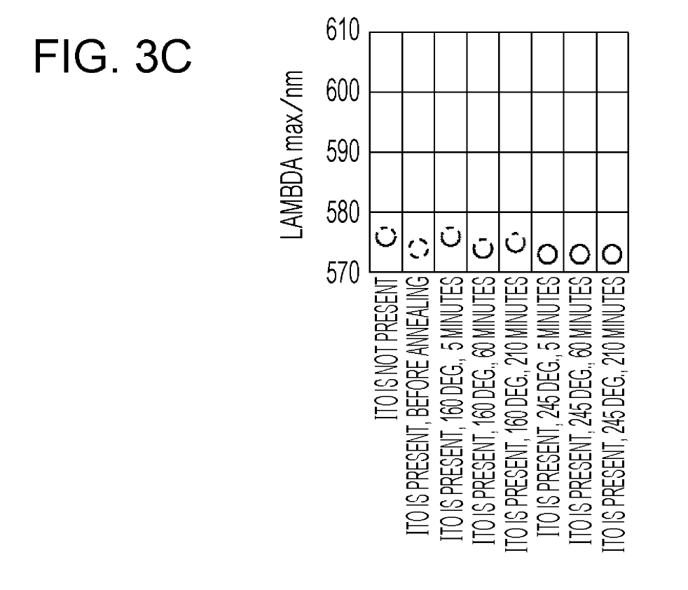

FIGS. 3A to 3C show the spectral properties of Samples 11 and 12 before and after the heating when mu-oxo-subphthalocyanine dimer was used as the organic thin film 22.

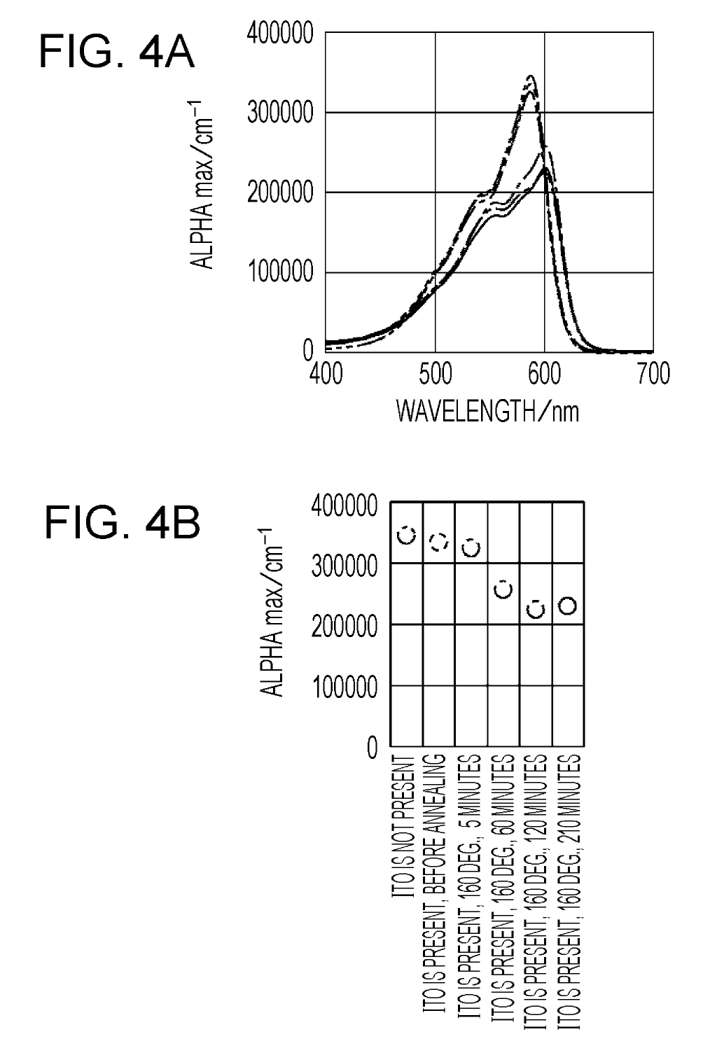

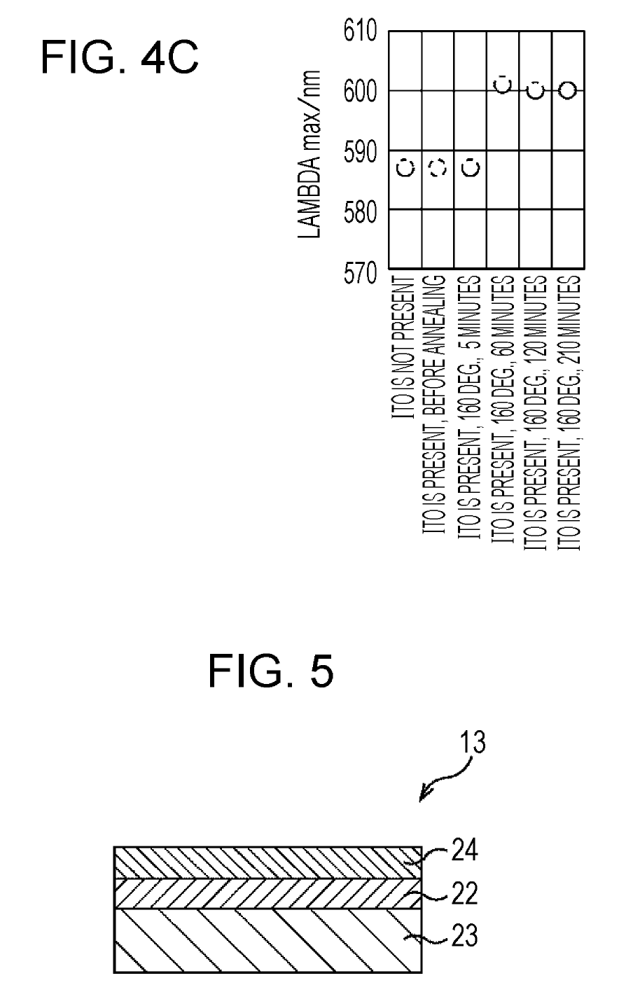

In contrast, FIGS. 4A to 4C show the spectral properties of Samples 11 and 12 before and after the heating when subphthalocyanine chloride was used as the organic thin film 22.

FIGS. 3A and 4A show spectral spectra, FIGS. 3B and 4B show absorbance alphamax, and FIGS. 3C and 4C show maximum absorption wavelengths lambdamax.

In comparison to the spectral spectra, spectral shapes substantially coincide with each other under any heating conditions regardless of whether or not the heating was performed in the case of mu-oxo-subphthalocyanine dimer shown in FIG. 3A, while the spectral shapes varied depending on the heating conditions in the case of subphthalocyanine chloride shown in FIG. 4A.

Similarly, values of the absorbance alphamax and the maximum absorption wavelengths lambdamax did not vary substantially under any heating conditions regardless of whether or not the heating was performed in the case of mu-oxo-subphthalocyanine dimer, while the values significantly varied as compared with those before the heating in the case of the subphthalocyanine chloride if the heating time was extended.

The absorbance alphamax is an index of color concentration, and the maximum absorption wavelengths lambdamax are indexes of color tones. Therefore, if subphthalocyanine chloride is used as a material for the organic photoelectric conversion film, the color property thereof unfavorably varies.

In contrast, there is no substantial variation in mu-oxo-subphthalocyanine dimer before and after the heating, and therefore, thermal stability (heat resistance) of the spectral shape is advantageously improved by multimerization.

<Experiment Regarding Variations in External Quantum Efficiency>

Next, description will be given of a second experiment for evaluating variations in external quantum efficiency when subphthalocyanine polymer and subphthalocyanine monomer are heated.

FIG. 5 shows an illustrative sample for evaluation that was produced for the second experiment.

In the second experiment, a device 13 was used, the device having a configuration in which the organic thin film 22 was interposed between the ITO film 23 and an AlSiCu film 24 as electrodes, as shown in FIG. 5. A film thickness of the ITO film 23 was set to about 50 nm, for example, and film thicknesses of the organic thin film 22 and the AlSiCu film 24 were set to about 100 nm, for example.

The device 13 was used to evaluate rates of change in the external quantum efficiency before and after the heating by using a light source, a filter, and a semi-conductor parameter analyzer. Specifically, the external quantum efficiency was calculated from a dark current value and a light current value when intensity of light with which the device 13 was irradiated was set from 0 microW/cm² to 5 microW/cm² and voltage applied between the electrodes was set to 1 V.

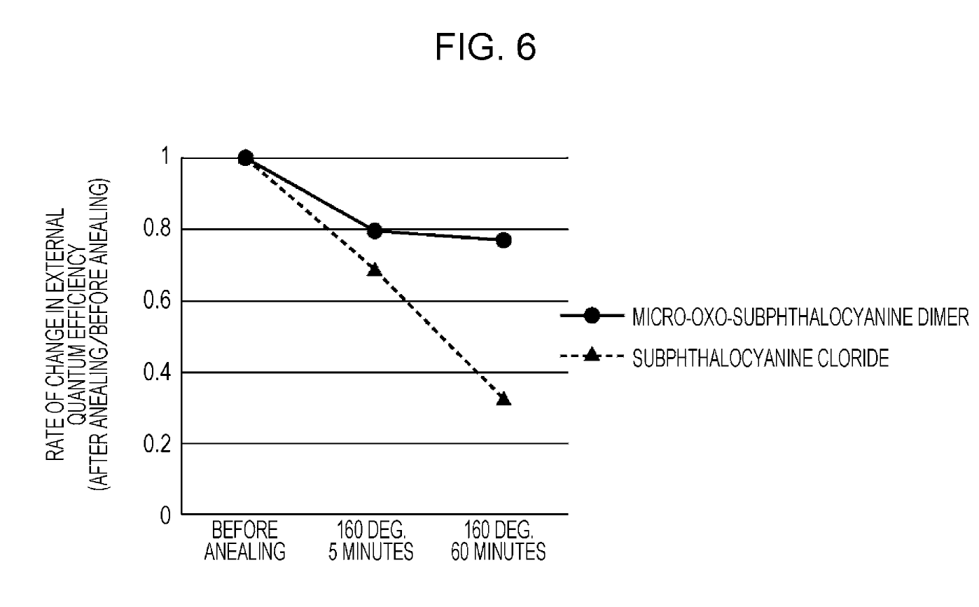

FIG. 6 shows an illustrative rate of change in the external quantum efficiency of the device 13 before and after the heating, as a result of the second experiment. In addition, the rate of change is represented by a ratio of the external quantum efficiency after annealing when a value of the external quantum efficiency before the annealing is set to one.

As shown in FIG. 6, the external quantum efficiency of subphthalocyanine chloride after the annealing decreased to about thirty percent while the external quantum efficiency of mu-oxo-subphthalocyanine dimer was maintained at about eighty percent of that before the annealing, even after the annealing. Therefore, thermal degradation of the external quantum efficiency was advantageously suppressed by multimerization.

<Consideration of Experiment Results

Results of the first and second experiments will be considered.

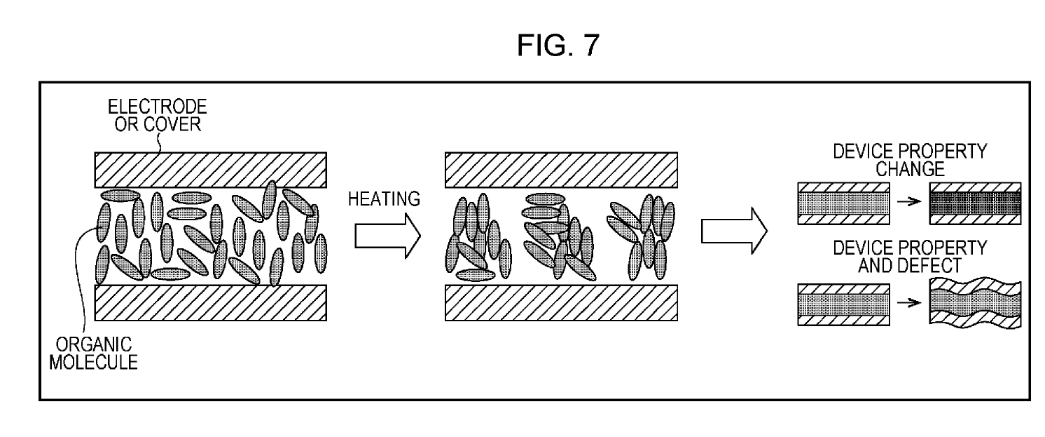

In the case of subphthalocyanine monomer, molecular migration occurs due to the heating as shown in FIG. 7. In addition, the migration causes molecular aggregation, and variations in orientation, among other problems. As a result, device properties such as a color tone and an electrical property vary, and deformation, defects, and other problems for the device are caused.

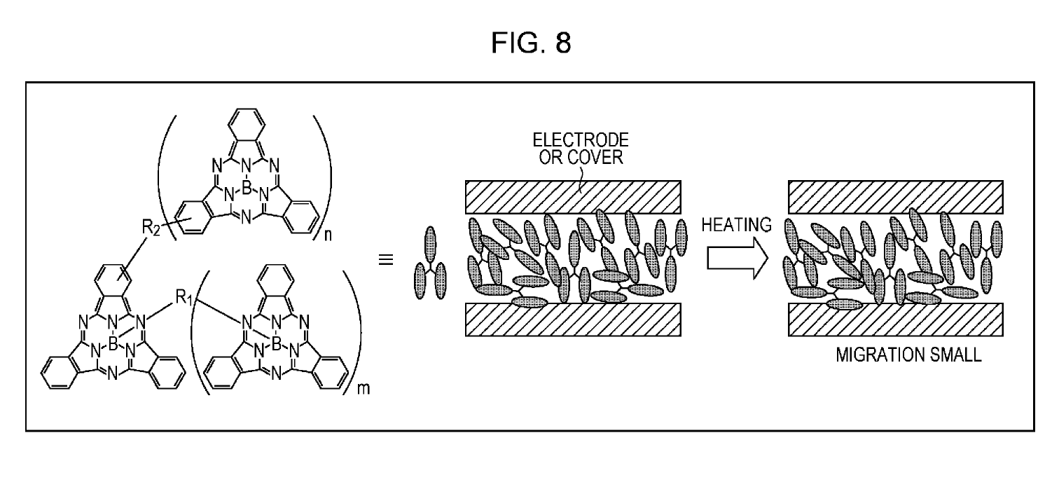

In contrast, in the case of subphthalocyanine polymer, thermal motion during the heating is advantageously suppressed by the multimerization as shown in FIG. 8, and aggregation energy increases due to an increase in molecular weight. Thus, molecular migration is advantageously suppressed and heat resistance is advantageously improved as a result.

In addition, it may be advantageous and/or necessary to control the molecular weight of subphthalocyanine polymer by a method of forming the organic thin film, and the molecular weight is from about 100 to about 2000 in the case of deposition and from about 2000 to about a million in the case of coating.

In addition, it is possible to form subphthalocyanine polymer not only before the film formation but also after the film formation by using heat, light, an additive, and other process variations. Examples of methods of causing multimerization by heat include a method of causing multimerization by depositing pigment, which contains a crosslinkable group and a polymerizable group, and heating the substrate after the film formation and thereby thermally starting a crosslinking reaction and a polymerization reaction. Examples of methods for causing multimerization by light include a method of causing multimerization by depositing pigment, which contains a crosslinkable group and a polymerizable group, and a photosensitizer, irradiating the substrate after the film formation with light, and thereby starting the crosslinking reaction and the polymerization reaction. Examples of multimerization by an additive include a method of causing multimerization by depositing pigment containing a functional group, which reacts with an additive, and the additive, causing reaction between the pigment and the additive by the aforementioned heat or the light after the film formation.

As described above, by causing the multimerization of the pigment containing the monomer which is used with a color filter, it was advantageously possible to improve the heat resistance without changing the color tone and the photoelectric conversion property, even if the thermal treatment was performed thereon. Accordingly, it is possible to advantageously generate a pigment which is suitable as a material of an organic photoelectric conversion film in a solid-state imaging device.

Examples of pigment that has absorbance in the ultraviolet to infrared regions (e.g., within a range from 10² A to 10⁶ A) and is capable of improving the heat resistance by causing the multimerization other than the aforementioned subphthalocyanine, include phthalocyanine, subporphyrazine, porphyrazine, quinacridone, perylene, anthraquinone, indigo, fullerene, and coumarin.

Each of subphthalocyanine, subporphyrazine, porphyrazine, quinacridone, and perylene is pigment with green absorption light and red color emission light. Each of phthalocyanine and indigo is pigment with red absorption light and blue color emission light. Each of fullerene and coumarin is pigment with blue absorption light and yellow color emission light. However, the colors vary depending on function groups and are therefore not limited thereto.

Phthalocyanine polymer can be represented by the following Formula (B2).

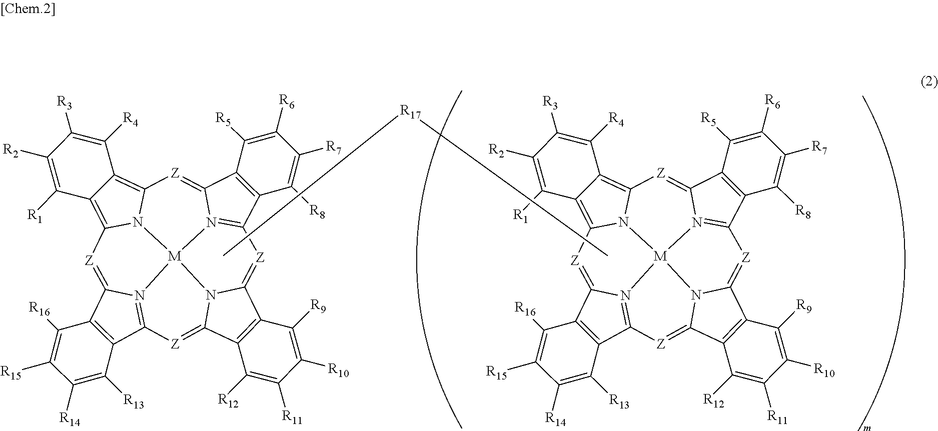

In Formula (B2), R₁ to R₁₆, M, and Z are independently selected, R₁ to R₁₆ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₁₇ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₁₆ may be a part of a condensed aliphatic ring or of a condensed aromatic ring, the ring may contain one or more atoms other than carbon atoms, and furthermore, R₁₇ is selected from a group of the functional groups used for R₁ to R₁₆ which are coupled with one or more phthalocyanines or a benzoporphyrin ring via M or a portion of any of R₁ to R₁₆, M is metal, Z is represented by N, CH, or CR₁₈, and R₁₈ is selected from a group of the functional groups used for R₁ to R₁₆.

Subporphyrazine polymer can be represented by the following Formula (B3).

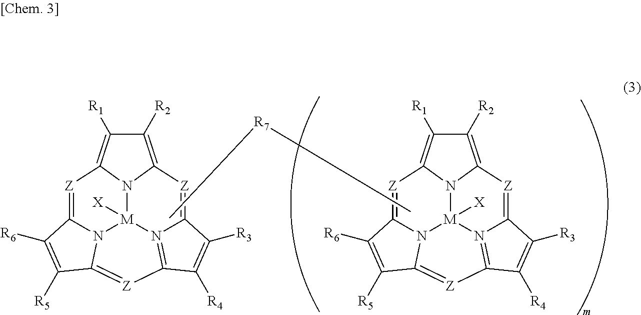

In Formula (B3), R₁ to R₇, M, and Z are independently selected, R₁ to R₇ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₇ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₇ may be a part of a condensed aliphatic ring or of a condensed aromatic ring, the ring may contain one or more atoms other than carbon atoms, and furthermore, R₇ is selected from a group of the functional groups used for R₁ to R₆ which are coupled with one or more subporphyrins or a subporphyrazine ring via M or a portion of any of R₁ to R₆, M is metal, Z is represented by N, CH, or CR₈, and R₈ is selected from a group of the functional groups used for R₁ to R₇.

Porphyrazine polymer can be represented by the following Formula (B4).

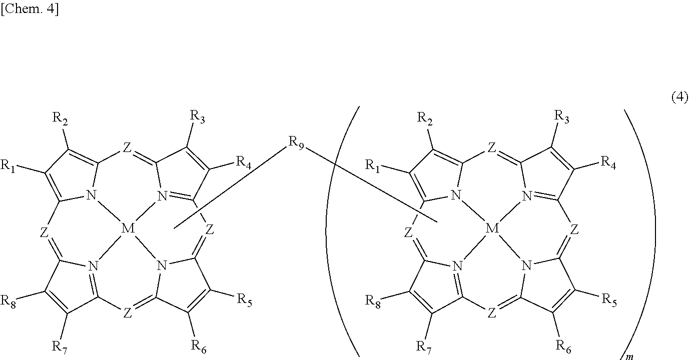

In Formula (B4), R₁ to R₉, M, and Z are independently selected, R₁ to R₉ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₉ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₉ may be a part of a condensed aliphatic ring or of a condensed aromatic ring, the ring may contain one or more atoms other than carbon atoms, and furthermore, R₉ is selected from a group of the functional groups used for R₁ to R₈ which are coupled with one or more porphyrins or a porphyrazine ring via M or a portion of any of R₁ to R₈, M is metal, Z is represented by N, CH, or CR₁₀, and R₁₀ is selected from a group of the functional groups used for R₁ to R₉.

Quinacridone polymer can be represented by the following Formula (B5).

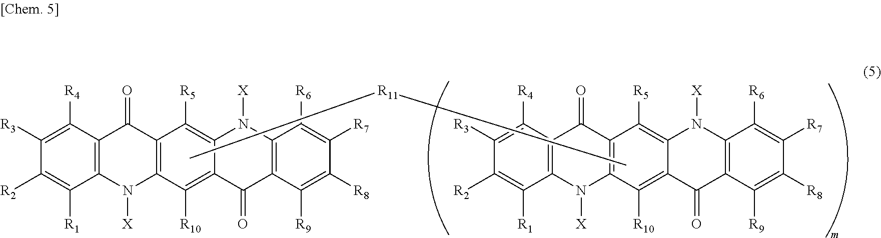

In Formula (B5), R₁ to R₁₁ and X are independently selected, R₁ to R₁₁ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₁₁ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₁₁ may be a part of a condensed aliphatic ring or of a condensed aromatic ring, the ring may contain one or more atoms other than carbon atoms, and furthermore, R₁₁ is selected from a group of the functional groups used for R₁ to R₁₀ which are coupled with one or more quinacridone rings via X or a portion of any of R₁ to R₁₀.

Perylene polymer can be represented by the following Formula (B6).

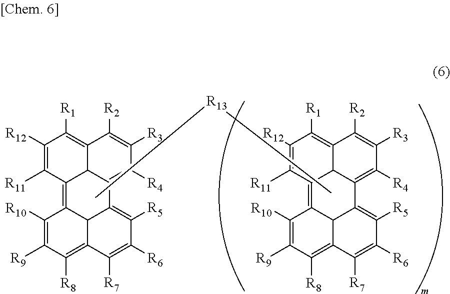

In Formula (B6), R₁ to R₁₃ are independently selected, R₁ to R₁₃ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₁₃ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₁₃ may be a part of a condensed aliphatic ring or of a condensed aromatic ring, the ring may contain one or more atoms other than carbon atoms, and furthermore, R₁₃ is selected from a group of the functional groups used for R₁ to R₁₂ which are coupled with one or more perylene rings via a portion of any of R₁ to R₁₂.

Anthraquinone polymer can be represented by the following Formula (B7).

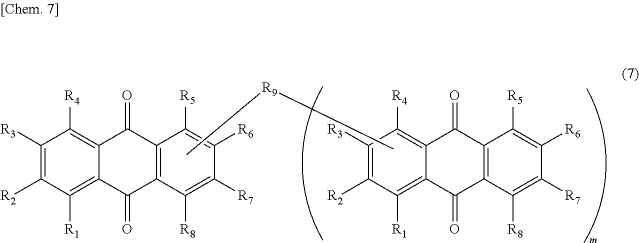

In Formula (B7), R₁ to R₉ are independently selected, R₁ to R₉ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₉ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₉ may be a part of a condensed aliphatic ring or of a condensed aromatic ring, the ring may contain one or more atoms other than carbon atoms, and furthermore, R₉ is selected from a group of the functional groups used for R₁ to R₈ which are coupled with one or more anthraquinone rings via a portion of any of R₁ to R

Indigo polymer can be represented by the following Formula (B8).

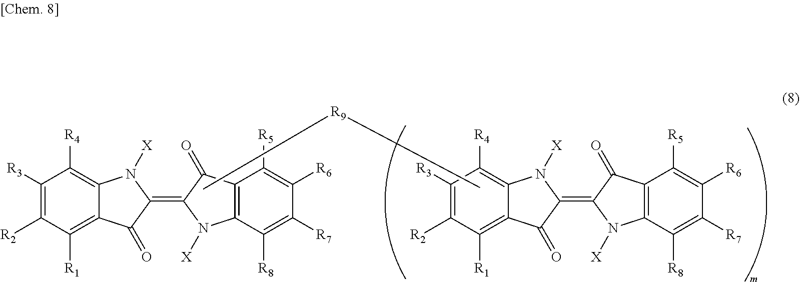

In Formula (B8), R₁ to R₉ and X are independently selected, R₁ to R₉ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₉ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₉ may be a part of a condensed aliphatic ring or of a condensed aromatic ring, the ring may contain one or more atoms other than carbon atoms, and furthermore, R₉ is selected from a group of the functional groups used for R₁ to R₈ which are coupled with one or more indigo rings via X or a portion of any of R₁ to R₈.

Fullerene polymer can be represented by the following Formula (B9).

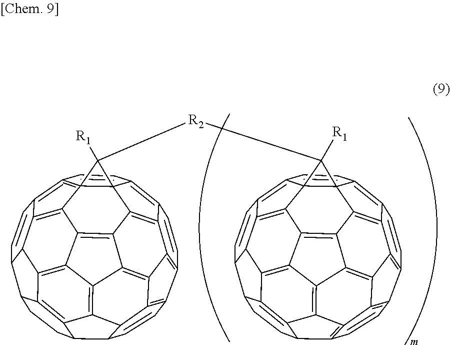

In Formula (B9), R₁ and R₂ are independently selected, R₁ and R₂ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ and R₂ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ and R₂ may be a part of a condensed aliphatic ring or of a condensed aromatic ring, the ring may contain one or more atoms other than carbon atoms, and furthermore, R₂ is selected from a group of the functional groups used for R₁ which is coupled with one or more fullerenes via a portion of R₁.

Coumarin polymer can be represented by the following Formula (B10).

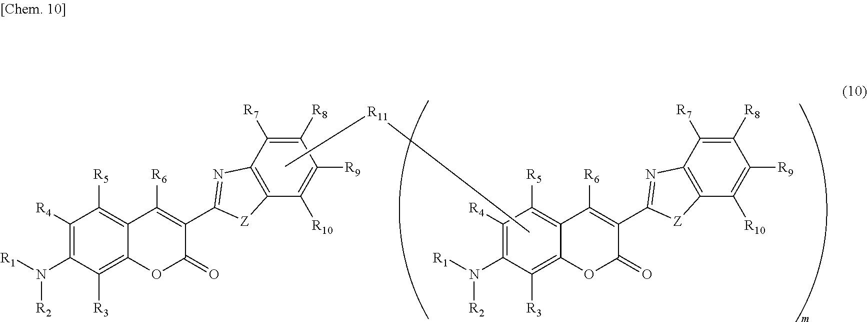

In Formula (B10), R₁ to R₁₁ and Z are independently selected, R₁ to R₁₁ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, arbitrary adjacent members from among R₁ to R₁₁ may be a part of a condensed aliphatic ring or of a condensed aromatic ring, the ring may contain one or more atoms other than carbon atoms, R₁ to R₁₁ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, R₁₁ is selected from a group of the functional groups used for R₁ to R₁₀ which are coupled with one or more coumarin rings via a portion of any of R₁ to R₈, Z is represented by O, S, CH, NH, CR₁₂, and NR₁₃, R₁₂ and R₁₃ are selected from a group of the functional groups used for R₁ to R₉, and R₁₂ and R₁₃ may be used for coupling a coumarin ring.

(Schematic Configuration Example of Solid-State Imaging Device)

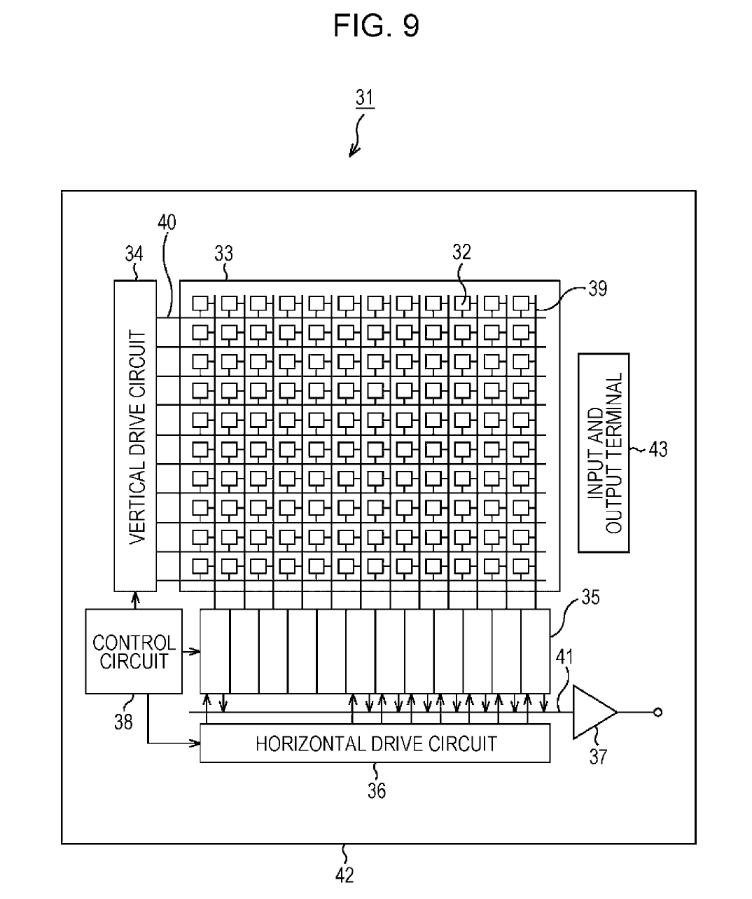

FIG. 9 shows an illustrative schematic configuration of the solid-state imaging device in which the aforementioned illustrative pigment after the multimerization is used as a material of the photoelectric conversion film.

A solid-state imaging device 31 in FIG. 9 is configured to include a pixel array section 33, in which pixels 32 are aligned in a two-dimensional array shape, and a peripheral circuit section in the periphery of the pixel array section 33 on a semiconductor substrate 42 in which silicon (Si) is used for a semiconductor. The peripheral circuit section includes a vertical drive circuit 34, a column signal processing circuit 35, a horizontal drive circuit 36, an output circuit 37, and a control circuit 38, among others.

Each of the pixels 32 includes a photodiode as a photoelectric conversion element and a plurality of pixel transistors. The plurality of pixel transistors are configured of four MOS transistors, namely a transfer transistor, a selection transistor, a reset transistor, and an amplification transistor, for example.

In addition, the pixels 32 can have a pixel shared structure. The pixel shared structure is configured of a plurality of photodiodes, a plurality of transfer transistors, a single floating diffusion (floating diffusion region) to be shared, and another single pixel transistor to be shared. That is, in the shared pixels, the photodiodes and the transfer transistors configuring a plurality of unit pixels share another single pixel transistor.

The control circuit 38 receives an input clock and data for instructing an operation mode and output data such as internal information of the solid-state imaging device 31. That is, the control circuit 38 generates a clock signal and a control signal as references of operations of the vertical drive circuit 34, the column signal processing circuit 35, and the horizontal drive circuit 36, among others, based on a vertical synchronization signal, a horizontal synchronization signal, and a master clock. In addition, the control circuit 38 outputs the generated clock signal and the control signal to the vertical drive circuit 34, the column signal processing circuit 35, and the horizontal drive circuit 36, among others.

The vertical drive circuit 34 is configured of a shift resister, for example, it selects a pixel drive wiring 40, supplies a pulse for driving the pixels 32 to the selected pixel drive wiring 40, and drives the pixels 32 in unit of rows. That is, the vertical drive circuit 34 selectively and sequentially scans the respective pixels 32 in the pixel array section 33 in the vertical direction in unit of rows and supplies a pixel signal on the basis of a signal charge generated by the photoelectric conversion sections in the respective pixels 32 in accordance with intensity of received light to the column signal processing circuit 35 via a vertical signal line 39.

The column signal processing circuit 35 is arranged in each array of the pixels 32 to perform signal processing, such as noise reduction, on a signal output from the pixels 32 corresponding to one row for each pixel column. For example, the column signal processing circuit 35 performs signal processing such as Correlated Double Sampling (CDS) for reducing fixed pattern noise specific to the pixels and AD conversion.

The horizontal drive circuit 36 is configured of a shift resister, for example, selects each column signal processing circuit 35 in order by sequentially outputting a horizontal scanning pulse, and causes each column signal processing circuit 35 to output a pixel signal to the horizontal signal line 41.

The output circuit 37 performs signal processing on the signal, which is sequentially supplied from each column signal processing circuit 35 via the horizontal signal line 41, and outputs the processed signal. The output circuit 37 performs only buffering in some cases and, in other cases, performs black level adjustment, array variation correction, and various kinds of digital signal processing, among others, for example. An input and output terminal 43 exchanges signals with external devices.

The solid-state imaging device 31 configured as described above is a CMOS image sensor of a so-called column AD scheme, in which the column signal processing circuit 35 for performing the CDS processing and the AD conversion processing is arranged for each pixel column.

(Configuration Example of Solid-State Imaging Device)

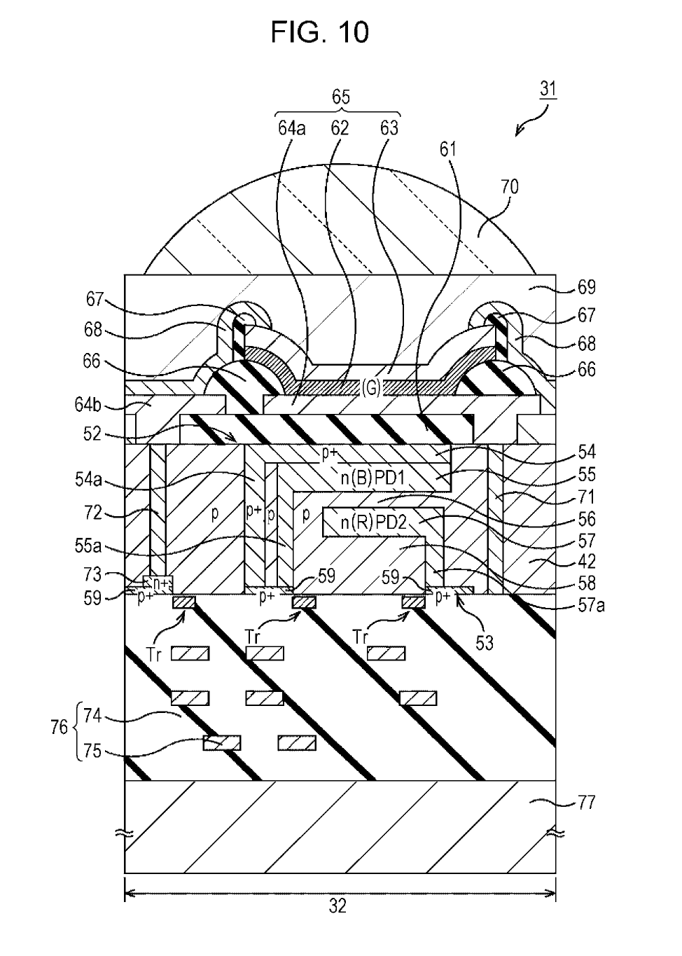

FIG. 10 is an illustrative cross-sectional view of a single pixel 32 in the pixel array section 33 of the solid-state imaging device 31 shown in FIG. 9.

The solid-state imaging device 31 is configured such that light is incident on a side of a rear surface 52 of the semiconductor substrate (silicon substrate) 42, on which the photodiodes PD1 and PD2 as will be described later are formed, and circuits including a so-called reading circuit are formed on a side of a front surface 53 of the semiconductor substrate 42. The semiconductor substrate 42 is configured of a semiconductor substrate of a first conductive type, for example, of a p-type.

In the semiconductor substrate 42, the photodiode PD1 and the photodiode PD2 as inorganic photoelectric conversion sections with two pn junctions are formed so as to be laminated on the side of the rear surface 52 in a depth direction. In the semiconductor substrate 42, a p-type semiconductor region 54 which functions as a hole storage layer, an n-type semiconductor region 55 which functions as a charge storage layer, a p-type semiconductor region 56, an n-type semiconductor region 57 which functions as a charge storage layer, and a p-type semiconductor region 58 which functions as a charge storage layer are formed in the depth direction from the side of the rear surface 52. The photodiode PD1 in which the n-type semiconductor region 55 is used as a charge storage layer is formed, and the photodiode PD2 in which the n-type semiconductor region 57 is used as a charge storage layer is formed.

According to this embodiment, the photodiode PD1 is for a blue color, and the photodiode PD2 is for a red color. The n-type semiconductor regions 55 and 57 partially extend so as to reach the front surface 53 of the semiconductor substrate 42 and form extending sections 55a and 57a, respectively. The extending sections 55a and 57a extend from opposite ends of the n-type semiconductor regions 55 and 57. In addition, p-type semiconductor regions 59 which function as hole storage layers are formed at interfaces with insulating films of the n-type semiconductor region 55 of the photodiode PD1 and at interfaces of the n-type semiconductor region 57 of the photodiode PD2, which face the front surface 53.

In contrast, an organic photoelectric conversion section 65 for a first color is formed as an upper layer on the rear surface 52 in a region, in which the photodiodes PD1 and PD2 are formed, via an insulating film 61. The organic photoelectric conversion section 65 is configured such that both the upper and lower surfaces of the organic photoelectric conversion film 62 are interposed between an upper electrode 63 and a lower electrode 64a. The upper electrode 63 and the lower electrode 64a are formed by transparent conductive films such as indium tin oxide (ITO) film or indium zinc oxide film. As the insulating film 61, a film with negative fixed charge, such as a hafnium oxide film may be used. Such a configuration may be advantageous for suppressing occurrence of dark current because a hole storage state at an interface between the p-type semiconductor region 54 and the insulating film 61 is enhanced.

According to this illustrative embodiment, the organic photoelectric conversion section 65 is for a green color, and pigment after multimerization, such as the aforementioned subphthalocyanine polymer or quinacridone polymer, is used as a material of the organic photoelectric conversion film 62.

Although the organic photoelectric conversion section 65 is for the green color, the photodiode PD1 is for the blue color, and the photodiode PD2 is for the red color as a color combination in this example; however, other color combinations are also applicable. For example, the organic photoelectric conversion section 65 can be for the red or blue color, and the photodiode PD1 and the photodiode PD2 can be set to other corresponding colors. In such a case, positions of the photodiodes PD1 and PD2 in the depth direction are set in accordance with the colors.

On the side of the rear surface 52 of the semiconductor substrate 42, transparent lower electrodes 64a and 64b, which are formed so as to be divided into two parts, are formed on the insulating film 61, and an insulating film 66 for insulation between both the lower electrodes 64a and 64b.

In addition, the organic photoelectric conversion film 62 and the transparent upper electrode 63 provided thereon are formed on the lower electrode 64a. Insulating films 67 for protection are formed on end surfaces of the patterned upper electrode 63 and the organic photoelectric conversion film 62, and in such a state, the upper electrode 63 is connected to the other lower electrode 64b via a contact metal layer 68 as a different conductive film.

By forming the insulating film 67 for protection, the end surface of the organic photoelectric conversion film 62 is protected, and contact between the organic photoelectric conversion film 62 and the lower electrode 64b can be suppressed. Since electrode material of the upper electrode 63 is selected in consideration of work function, there is a possibility that dark current is generated at the end surface, for example, a side wall of the organic photoelectric conversion film 62 if different electrode materials are brought into contact at the side wall of the organic photoelectric conversion film 62. In addition, because the organic photoelectric conversion film 62 and the upper electrode 63 are uniformly formed, a satisfactory interface is formed. However, the side wall of the organic photoelectric conversion film 62 after patterning by dry etching or other processes does not have a satisfactory surface, and there is a possibility that the interface deteriorates and dark current increases if different electrode materials are brought into contact.

Above the organic photoelectric conversion section 65 and the contact metal layer 68, an on-chip lens 70 is formed via a flattening film 69. Therefore, no color filter is formed in this structure.

A pair of conductive plugs 71 and 72 that penetrate through the semiconductor substrate 42 are formed in each pixel 32. The lower electrode 64a of the organic photoelectric conversion section 65 is connected to the conductive plug 71, and the lower electrode 64b which is connected to the upper electrode 63 is connected to the other conductive plug 72.

The conductive plugs 71 and 72 can be formed by W plugs which have SiO2 or SiN insulating layers in the peripheries thereof in order to suppress a short circuit with Si, for example, or by semiconductor layers by ion implantation. Since electrons are used as a signal charge in this embodiment, the conductive plug 71 is formed as an n-type semiconductor layer in a case of being formed as a semiconductor layer by the ion implantation. The upper electrode 63 may be formed as a p-type layer for the extracting holes.

In this example, an n-type semiconductor region 73 for charge storage is formed on the side of the front surface 53 of the semiconductor substrate 42 in order to store the electrons, which are used as a signal charge from among pairs of electrons and holes after being subjected to the photoelectric conversion by the organic photoelectric conversion section 65, via the upper electrode 63 and the conductive plug 72.

On the side of the front surface 53 of the semiconductor substrate 42, pixel transistor Tr as a part of the reading circuit is formed so as to correspond to each of the organic photoelectric conversion section 65, the photodiode PD1, and the photodiode PD2.

Above the front surface 53 of the semiconductor substrate 42, multilayered wiring layer 76, in which wiring 75 in a plurality of layers is arranged, is formed via an interlayer insulating film 74. A support substrate 77 is attached to the multilayered wiring layer 76.

As described above, the solid-state imaging device 31 is a rear surface irradiation-type solid-state imaging device that receives light from the side of the rear surface 52 of the semiconductor substrate 42. In addition, the solid-state imaging device 31 is a longitudinal direction spectral-type solid-state imaging device in which the plurality of photoelectric conversion sections, namely the organic photoelectric conversion section 65 for the first color, the photodiode PD1 for the second color, and the photodiode PD2 for the third color, are arranged in the longitudinal direction (e.g., depth direction) in each pixel 32.

In the solid-state imaging device 31 as described above, the aforementioned pigment after the multimerization, such as subphthanlocyanine polymer or quinacridone polymer, is used as a material of the organic photoelectric conversion film 62 of the organic photoelectric conversion section 65. Because the heat resistance of the pigment after the multimerization is improved as described above, it is possible to prevent the color tone and the photoelectric conversion property from varying even if heat treatment is performed, and therefore, such pigment may be advantageous as the material of the organic photoelectric conversion film 62 in the solid-state imaging device 31.

In addition, the present disclosure is not limited to the rear surface irradiation-type solid-state imaging device, and it is a matter of course that pigment after multimerization may be used as a material of a photoelectric conversion film in a front surface irradiation-type solid-state imaging device.

(Example of Application to Electronic Apparatus)

The technology described in the present disclosure is not limited to an application to the solid-state imaging device. That is, the technology described in the present disclosure can be applied to all the electronic apparatuses, in each of which a solid-state imaging device is used for an image importing section (photoelectric conversion section), such as imaging apparatuses including a digital still camera and a video camera, a mobile terminal apparatus with an imaging function, and a copy machine in which the solid-state imaging device is used for an image reading unit. The solid-state imaging device may be in the form of one chip or in the form of a module with an imaging function, in which an imaging section and a signal processing section or an optical system are collectively packaged.

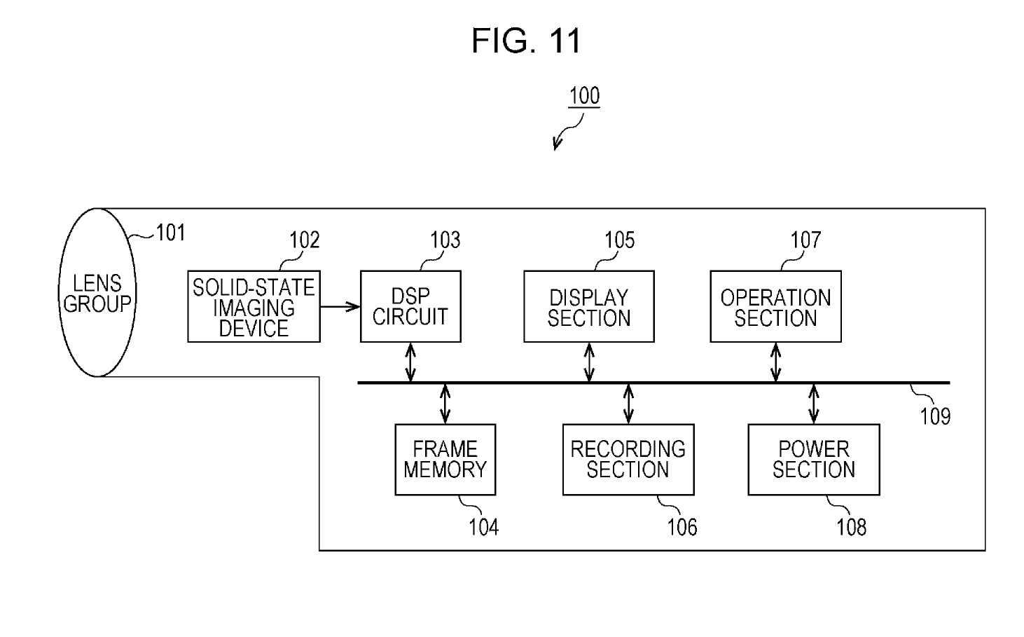

FIG. 11 is an illustrative block diagram showing a configuration example of an imaging apparatus as the electronic apparatus described in the present disclosure.

An imaging apparatus 100 in FIG. 11 is provided with an optical section 101 including a lens group, a solid-state imaging device (imaging device) 102 for which the configuration of the solid-state imaging device 31 in FIG. 9 is employed, and a digital signal processor (DSP) circuit 103 as a camera signal processing circuit. In addition, the imaging apparatus 100 is also provided with a frame memory 104, a display section 105, a recording section 106, an operation section 107, and a power section 108. The DSP circuit 103, the frame memory 104, the display section 105, the recording section 106, the operation section 107, and the power section 108 are connected to each other via a bus line 109.

The optical section 101 receives incident light (e.g., image light) from an object and forms an image on an imaging surface of the solid-state imaging device 102. The solid-state imaging device 102 converts light intensity of the incident light, an image of which is formed on the imaging surface by the optical section 101, into an electric signal in unit of pixels, and outputs the electric signal as a pixel signal. As the solid-state imaging device 102, the solid-state imaging device 31 shown in FIG. 9, namely the longitudinal direction spectral-type solid-state imaging device in which the material of the photoelectric conversion film with the improved heat resistance is used, can be used.

The display section 105 is configured of a panel-type display device such as a liquid crystal panel or an organic electroluminescense (EL) panel and displays a moving image or a stationary image captured by the solid-state imaging device 102. The recording section 106 records the moving image or the stationary image captured by the solid-state imaging device 102 on a recording medium such as a hard disk or a semiconductor memory.

The operation section 107 provides an operation command for various functions of the imaging apparatus 100 in response to operations by a user. The power section 108 supplies various power sources as operation power sources of the DSP circuit 103, the frame memory 104, the display section 105, the recording section 106, and the operation section 107 to these supply targets as necessary.

By using the solid-state imaging device 31 according to the aforementioned illustrative embodiment as the solid-state imaging device 102 as described above, it is advantageously possible to prevent the color tone and the photoelectric conversion property from varying due to the heat treatment. Accordingly, it is possible to advantageously improve quality of images captured by the imaging apparatus 100 such as a video camera, a digital camera, or a camera module for a mobile device such as a mobile phone.

Although the aforementioned example was described as the case of the solid-state imaging device in which the first conductive type was the p type, the second conductive type was the n type, and electrons were used as a signal charge, this technology can also be applied to a solid-state imaging device in which holes are used as a signal charge. That is, the aforementioned respective semiconductor regions can be configured as semiconductor regions of opposite conductive types by setting the first conductive type to the n type and setting the second conductive type to the p type.

The embodiments of the present disclosure are not limited to the aforementioned illustrative embodiments, and various modifications can be made without departing from the gist of the present disclosure.

For example, it is possible to employ a configuration in which entireties or parts of all the plurality of aforementioned embodiments are combined.

In addition, advantages are described herein only for an illustrative purpose and are not limited thereto, and advantages other than those described herein may be achieved.

Moreover, the present disclosure may also be implemented in the following configurations.

(A1) A solid-state imaging device including: a pixel which has an organic photoelectric conversion section which performs photoelectric conversion by an organic photoelectric conversion film, wherein the organic photoelectric conversion film is formed by pigment which is configured of polymer with absorbance in ultraviolet to infrared regions.

(A2) The solid-state imaging device according to (A1), wherein the pigment is subphthalocyanine polymer which is represented by the following Formula (A1).

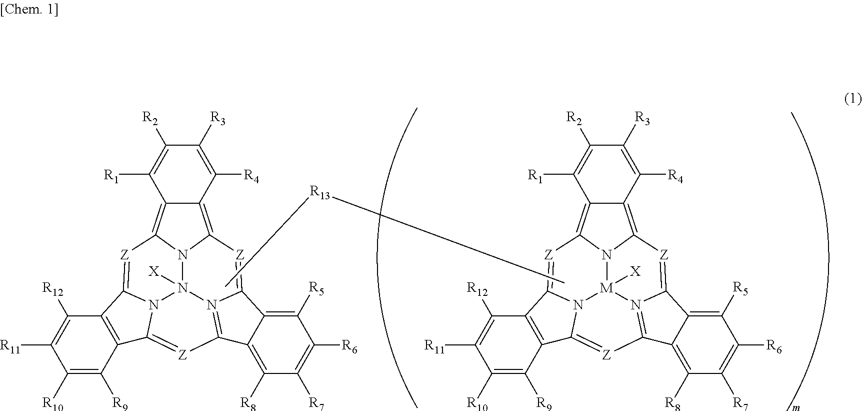

(In Formula (A1), R₁ to R₁₂, M, X, and Z are independently selected, R₁ to R₁₂ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₁₃ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₁₂ may be a part of a condensed aliphatic ring or of a condensed aromatic ring, the ring may contain one or more atoms other than carbon atoms, and furthermore, R₁₃ is selected from a group of the functional groups used for R₁ to R₁₂ which are coupled with one or more subphthalocyanines or a subporphyrin ring via M or a portion of any of R₁ to R₁₂, M is boron, bivalent metal, or trivalent metal, X is selected from a group including an anionic group which is introduced when R₁₃ is not directly coupled with M and the group of the functional groups which are used for R₁ to R₁₂ that can be coupled with M, Z is represented by N, CH, or CR₁₄, and R₁₄ is selected from a group of the functional groups used for R₁ to R₁₂.)

(A3) The solid-state imaging device according to (A1), wherein the pigment is phthalocyanine polymer which is represented by the following Formula (A2).

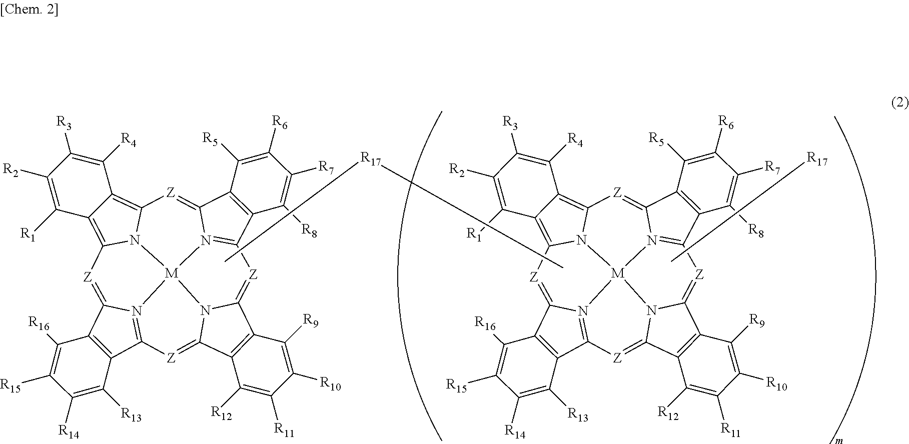

(In Formula 2, R₁ to R₁₆, M, and Z are independently selected, R₁ to R₁₆ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₁₇ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₁₆ may be a part of a condensed aliphatic ring or of a condensed aromatic ring, the ring may contain one or more atoms other than carbon atoms, and furthermore, R₁₇ is selected from a group of the functional groups used for R₁ to R₁₆ which are coupled with one or more bphthalocyanines or a benzoporphyrin ring via M or a portion of any of R₁ to R₁₆, M is metal, Z is represented by N, CH, or CR₁₈, and R₁₈ is selected from a group of the functional groups used for R₁ to R₁₆.)

(A4) The solid-state imaging device according to (A1), wherein the pigment is subporphyrazine polymer which is represented by the following Formula (A3).

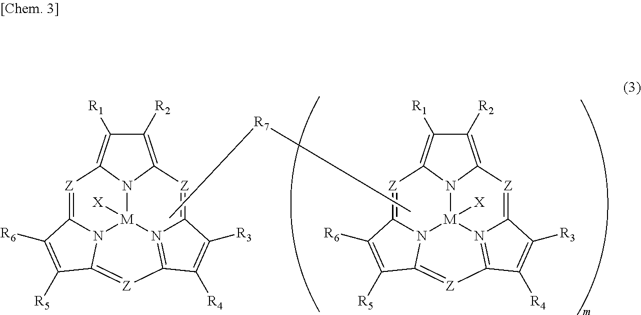

(In Formula (A3), R₁ to R₇, M, and Z are independently selected, R₁ to R₇ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₇ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₇ may be a part of a condensed aliphatic ring or of a condensed aromatic ring, the ring may contain one or more atoms other than carbon atoms, and furthermore, R₇ is selected from a group of the functional groups used for R₁ to R₆ which are coupled with one or more subporphyrins or a subporphyrazine ring via M or a portion of any of R₁ to R₆, M is metal, Z is represented by N, CH, or CR₈, and R₈ is selected from a group of the functional groups used for R₁ to R₇.)

(A5) The solid-state imaging device according to (A1), wherein the pigment is porphyrazine polymer which is represented by the following Formula (A4).

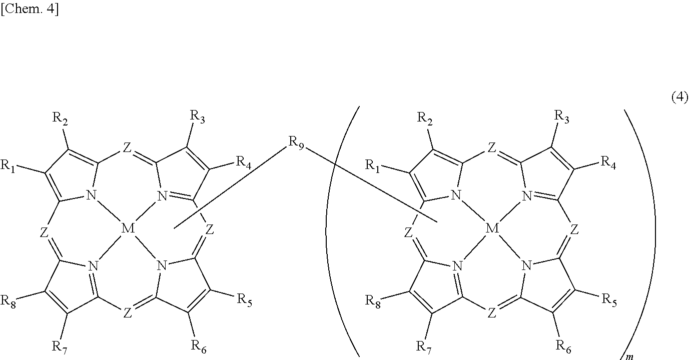

(In Formula (A4), R₁ to R₉, M, and Z are independently selected, R₁ to R₉ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₉ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₉ may be a part of a condensed aliphatic ring or of a condensed aromatic ring, the ring may contain one or more atoms other than carbon atoms, and furthermore, R₉ is selected from a group of the functional groups used for R₁ to R₈ which are coupled with one or more porphyrins or a porphyrazine ring via M or a portion of any of R₁ to R₈, M is metal, Z is represented by N, CH, or CR₁₀, and R₁₀ is selected from a group of the functional groups used for R₁ to R₉.)

(A6) The solid-state imaging device according to (A1), wherein the pigment is quinacridone polymer which is represented by the following Formula (A5).

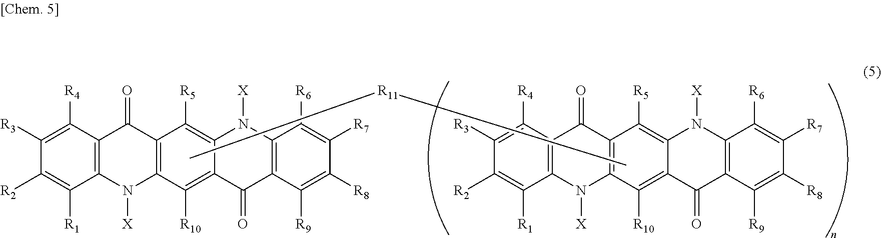

(In Formula (A5), R₁ to R₁₁ and X are independently selected, R₁ to R₁₁ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₁₁ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₁₁ may be a part of a condensed aliphatic ring or of a condensed aromatic ring, the ring may contain one or more atoms other than carbon atoms, and furthermore, R₁₁ is selected from a group of the functional groups used for R₁ to R₁₀ which are coupled with one or more quinacridone rings via X or a portion of any of R₁ to R₁₀.)

(A7) The solid-state imaging device according to (A1), wherein the pigment is perylene polymer which is represented by the following Formula (A6).

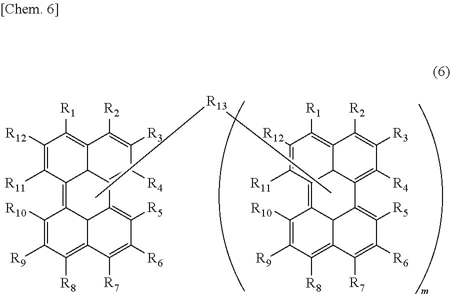

(In Formula (A6), R₁ to R₁₃ are independently selected, R₁ to R₁₃ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₁₃ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₁₃ may be a part of a condensed aliphatic ring or of a condensed aromatic ring, the ring may contain one or more atoms other than carbon atoms, and furthermore, R₁₃ is selected from a group of the functional groups used for R₁ to R₁₂ which are coupled with one or more perylene rings via a portion of any of R₁ to R₁₂.)

(A8) The solid-state imaging device according to (A1), wherein the pigment is anthraquinone polymer which is represented by the following Formula (A7).

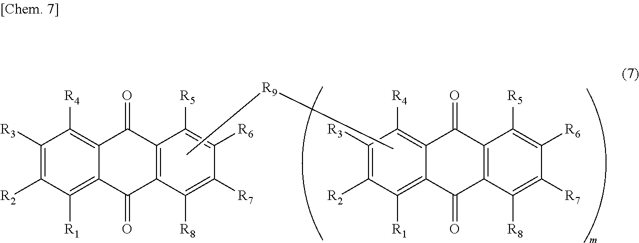

(In Formula (A7), R₁ to R₉ are independently selected, R₁ to R₉ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₉ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₉ may be a part of a condensed aliphatic ring or of a condensed aromatic ring, the ring may contain one or more atoms other than carbon atoms, and furthermore, R₉ is selected from a group of the functional groups used for R₁ to R₈ which are coupled with one or more anthraquinone rings via a portion of any of R₁ to R₈.)

(A9) The solid-state imaging device according to (A1), wherein the pigment is indigo polymer which is represented by the following Formula (A8).

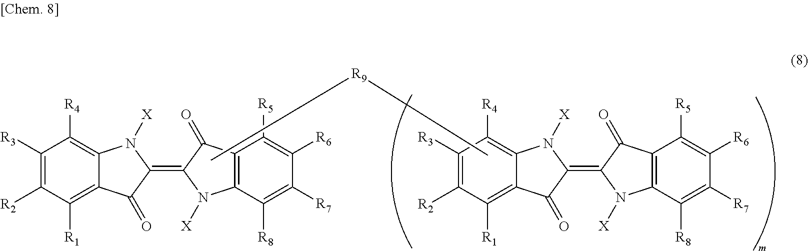

(In Formula (A8), R₁ to R₉ and X are independently selected, R₁ to R₉ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ to R₉ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ to R₉ may be a part of a condensed aliphatic ring or of a condensed aromatic ring, the ring may contain one or more atoms other than carbon atoms, and furthermore, R₉ is selected from a group of the functional groups used for R₁ to R₈ which are coupled with one or more indigo rings via X or a portion of any of R₁ to R₈.)

(A10) The solid-state imaging device according to (A1), wherein the pigment is fullerene polymer which is represented by the following Formula (A9).

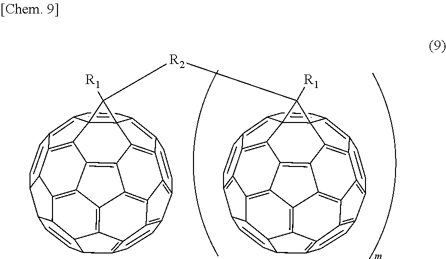

(In Formula (A9), R₁ and R₂ are independently selected, R₁ and R₂ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, R₁ and R₂ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, arbitrary adjacent members from among R₁ and R₂ may be a part of a condensed aliphatic ring or of a condensed aromatic ring, the ring may contain one or more atoms other than carbon atoms, and furthermore, R₂ is selected from a group of the functional groups used for R₁ which is coupled with one or more fullerenes via a portion of any of R₁.)

(A11) The solid-state imaging device according to (A1), wherein the pigment is coumarin polymer which is represented by the following Formula (A10).

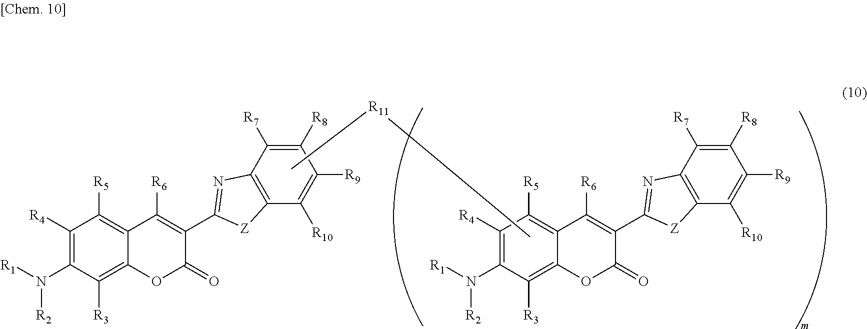

(In Formula (A10), R₁ to R₁₁ and Z are independently selected, R₁ to R₁₁ are independently selected from a group including H, linear, branched, or cyclic alkyl, phenyl, a linear or condensed aromatic ring, partial fluoroalkyl, perfluoroalkyl, halide, silylalkyl, silylalkoxy, arylsilyl, thioalkyl, thioaryl, arylsulfonyl, alkylsulfonyl, amino, alkylamino, arylamino, hydroxy, alkoxy, acylamino, acyloxy, carboxy, carboxyamide, carboalkoxy, acyl, sulfonyl, cyano, and nitro, arbitrary adjacent members from among R₁ to R₁₁ may be a part of a condensed aliphatic ring or of a condensed aromatic ring, the ring may contain one or more atoms other than carbon atoms, R₁ to R₁₁ may be any organic polymerizable functional group from among a vinyl group, an allyl group, a (meth)acryl group, a glycidyl group, an aziridine ring, an isocyanate group, conjugated diene, acid anhydride, acid chloride, a carbonyl group, a hydroxyl group, an amide group, an amino group, a chloromethyl group, an ester group, a formyl group, a nitrile group, a nitro group, a carbodiimide group, and an oxazoline group, R₁₁ is selected from a group of the functional groups used for R₁ to R₁₀ which are coupled with one or more coumarin rings via a portion of any of R₁ to R₈, Z is represented by O, S, CH, NH, CR₁₂, and NR₁₃, R₁₂ and R₁₃ are selected from a group of the functional groups used for R₁ to R₉, and R₁₂ and R₁₃ may be used for coupling a coumarin ring.)

(A12) The solid-state imaging device according to any one of (A1) to (A11), wherein in the pixel, an inorganic photoelectric conversion section including a pn junction with the organic photoelectric conversion section is laminated in a depth direction of a semiconductor substrate.

(A13) The solid-state imaging device according to any one of (A1) to (A12), wherein the organic photoelectric conversion section has a configuration in which upper and lower surfaces of the organic photoelectric conversion film are interposed between transparent electrodes.

(A14) The solid-state imaging device according to any one of (A1) to (A13), wherein the solid-state imaging device is of a rear face irradiation type.

(A15) An electronic apparatus including: a solid-state imaging device including a pixel which has an organic photoelectric conversion section which performs photoelectric conversion by an organic photoelectric conversion film, the organic photoelectric conversion film being formed by pigment which is configured of polymer with absorbance in ultraviolet to infrared regions.

(B1) A solid-state imaging device including: a pixel which has an organic photoelectric conversion section which performs photoelectric conversion by an organic photoelectric conversion film, wherethe organic photoelectric conversion film is formed by pigment which is configured of polymer with absorbance in ultraviolet to infrared regions.

(B2) The solid-state imaging device according to (B1), where the pigment is subphthalocyanine polymer as described herein.

(B3) A solid-state imaging device, including: a pixel including an organic photoelectric conversion section, the organic photoelectric conversion section including an organic photoelectric conversion film, the organic photoelectric conversion film performing photoelectric conversion; a pigment included in the organic photoelectric conversion film, the pigment being two or more polymerized monomers, and the pigment having absorbance in ultraviolet to infrared regions.

(B4) The solid-state imaging device according to (B3), where the pigment is a subphthalocyanine derivative having a formula of:

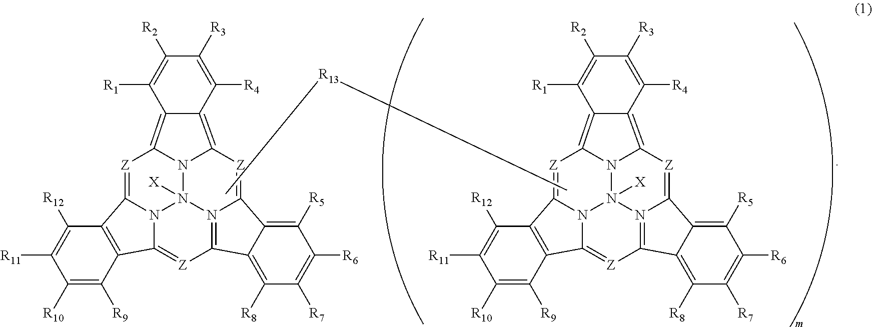

(B5) The solid-state imaging device according to claim (B3), where the pigment is a quinacridone derivative having a formula of:

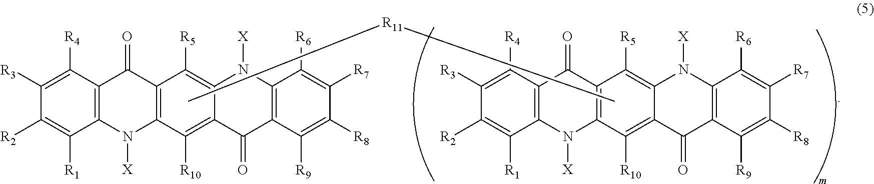

(B6) The solid-state imaging device according to claim (B3), where the pigment is a fullerene derivative having a formula of:

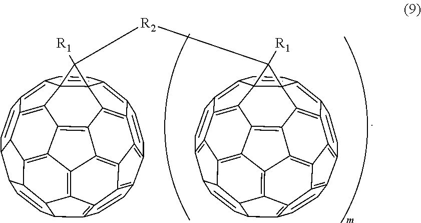

(B7) The solid-state imaging device according to (B3), where the pigment is one of a subphthalocyanine polymer, a quinacridone polymer, or a fullerene polymer.

(B8) The solid-state imaging device according to (B3), where the pigment is one of a subphthalocyanine oligomer, a quinacridone oligomer, or a fullerene oligomer.

(B9) The solid-state imaging device according to (B3), where the pigment includes at least three polymerized monomers.

(B10) The solid-state imaging device according to (B3), where the pigment is a subphthalocyanine dimer.

(B11) The solid-state imaging device according to (B3), where the pigment is a quinacridone dimer.

(B12) The solid-state imaging device according to (B3), where the pigment is a fullerene dimer.

(B13) The solid-state imaging device according to (B3), where the pigment is a mu-oxo-subphthalocyanine dimer.

(B14) The solid-state imaging device according to (B3), where the solid-state imaging device further includes a silicon substrate such that the pixel is positioned over the silicon substrate to absorb light in the blue and red wavelengths.

(B15) The solid-state imaging device according to (B3), where the solid-state imaging device further includes a silicon substrate such that the pixel is positioned over the silicon substrate to absorb light in the green wavelength, and the pigment is one of sub-phthalocyanine and quinacridone.

(B16) An electronic apparatus, including: a solid-state imaging device, including: a pixel including an organic photoelectric conversion section, the organic photoelectric conversion section including an organic photoelectric conversion film, the organic photoelectric conversion film performing photoelectric conversion; a pigment included in the organic photoelectric conversion film, the pigment being two or more polymerized monomers, and the pigment having absorbance in ultraviolet to infrared regions.

(B17) The electronic apparatus according to (B16), where the pigment is a subphthalocyanine derivative having a formula of:

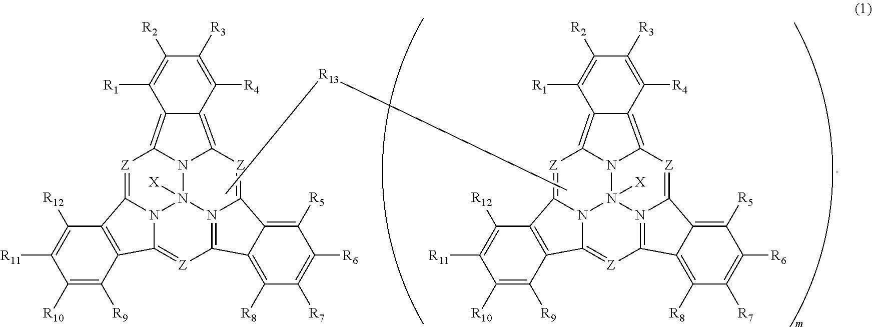

(B18) The electronic apparatus according to (B16), where the pigment is a quinacridone derivative having a formula of:

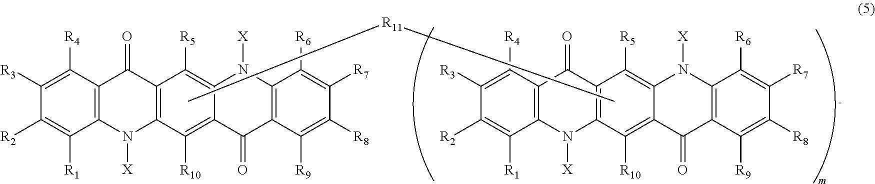

(B19) The electronic apparatus according to (B16), where the pigment is a fullerene derivative having a formula of:

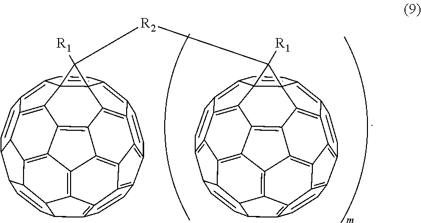

(B20) The electronic apparatus according to (B16), where the pigment is one of a subphthalocyanine polymer, a quinacridone polymer, or a fullerene polymer.

(B21) The electronic apparatus according to (B16), where the pigment is one of a subphthalocyanine oligomer, a quinacridone oligomer, or a fullerene oligomer.

(B22) The electronic apparatus according to (B16), where the pigment includes at least three polymerized monomers.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

22: Organic thin film

31: Solid-state imaging device

32: Pixel

42: Semiconductor substrate

62: Organic photoelectric conversion film

63: Upper electrode

64a: Lower electrode

65: Organic photoelectric conversion section

PD1, PD2: Photodiode

101: Imaging apparatus

102: Solid-state imaging device

1. A solid-state imaging device, comprising:
a pixel including an organic photoelectric conversion section, the organic photoelectric conversion section including an organic photoelectric conversion film, the organic photoelectric conversion film performing photoelectric conversion;
a pigment included in the organic photoelectric conversion film, the pigment being two or more polymerized monomers, and the pigment having absorbance in ultraviolet to infrared regions.

2. The solid-state imaging device according to claim 1, wherein the pigment is a subphthalocyanine derivative having a formula of:

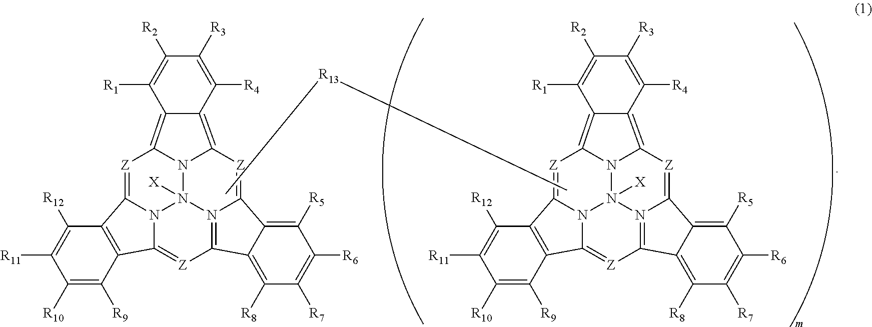

3. The solid-state imaging device according to claim 1, wherein the pigment is a quinacridone derivative having a formula of:

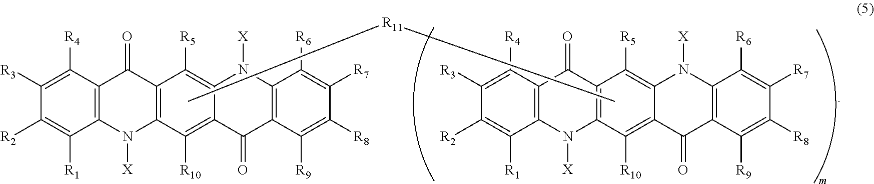

4. The solid-state imaging device according to claim 1, wherein the pigment is a fullerene derivative having a formula of:

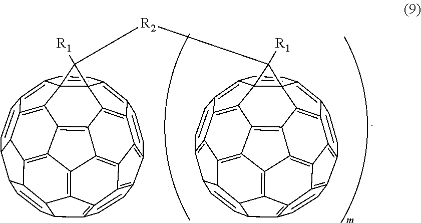

5. The solid-state imaging device according to claim 1, wherein the pigment is one of a subphthalocyanine polymer, a quinacridone polymer, or a fullerene polymer.

6. The solid-state imaging device according to claim 1, wherein the pigment is one of a subphthalocyanine oligomer, a quinacridone oligomer, or a fullerene oligomer.

7. The solid-state imaging device according to claim 1, wherein the pigment includes at least three polymerized monomers.

8. The solid-state imaging device according to claim 1, wherein the pigment is a subphthalocyanine dimer.

9. The solid-state imaging device according to claim 1, wherein the pigment is a quinacridone dimer.

10. The solid-state imaging device according to claim 1, wherein the pigment is a fullerene dimer.

11. The solid-state imaging device according to claim 1, wherein the pigment is a mu-oxo-subphthalocyanine dimer.

12. The solid-state imaging device according to claim 1, wherein the solid-state imaging device further comprises a silicon substrate such that the pixel is positioned over the silicon substrate to absorb light in the blue and red wavelengths.

13. The solid-state imaging device according to claim 1, wherein the solid-state imaging device further comprises a silicon substrate such that the pixel is positioned over the silicon substrate to absorb light in the green wavelength, and the pigment is one of subphthalocyanine and quinacridone.

14. An electronic apparatus, comprising:
a solid-state imaging device, including:
a pixel including an organic photoelectric conversion section, the organic photoelectric conversion section including an organic photoelectric conversion film, the organic photoelectric conversion film performing photoelectric conversion;
a pigment included in the organic photoelectric conversion film, the pigment being two or more polymerized monomers, and the pigment having absorbance in ultraviolet to infrared regions.

15. The electronic apparatus according to claim 14, wherein the pigment is a subphthalocyanine derivative having a formula of:

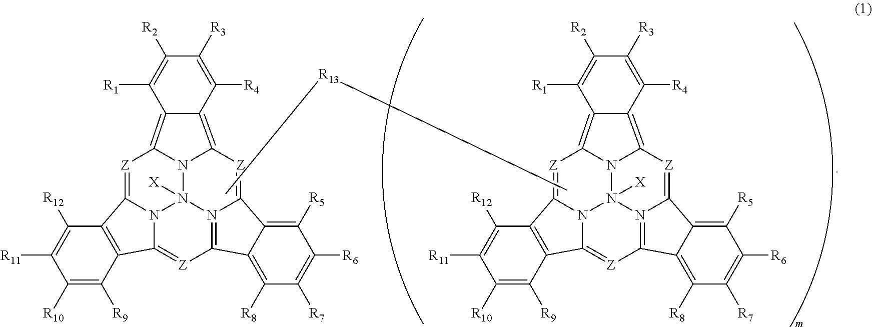

16. The electronic apparatus according to claim 14, wherein the pigment is a quinacridone derivative having a formula of:

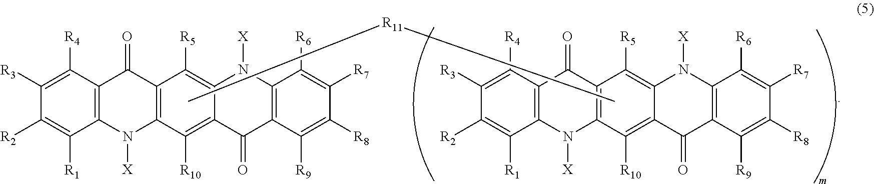

17. The electronic apparatus according to claim 14, wherein the pigment is a fullerene derivative having a formula of:

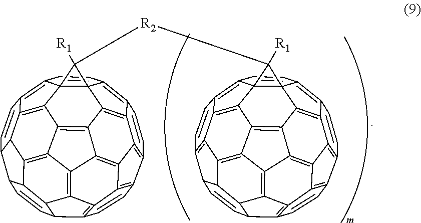

18. The electronic apparatus according to claim 14, wherein the pigment is one of a subphthalocyanine polymer, a quinacridone polymer, or a fullerene polymer.

19. The electronic apparatus according to claim 14, wherein the pigment is one of a subphthalocyanine oligomer, a quinacridone oligomer, or a fullerene oligomer.

20. The electronic apparatus according to claim 14, wherein the pigment includes at least three polymerized monomers.
